(19) United States
(12) Patent Application Publication
(10) Pub. No.: US 2008/0218158 A1
(43) Pub. Date: Sep. 11, 2008

(54) Rotary position sensor

(76) Inventors: Joseph D. Carlson, Elkhart, IN (US); William Storrie, Wishaw (GB); Russell S. Brayton, Elkhart, IN (US); Stephen Stepke, Granger, IN (US); Eric Fromer, Elkhart, IN (US); Kim Cook, Wakarusa, IN (US)

Correspondence Address: Daniel J. Deneufbourg, Esq.;CTS Corporation, 171 Covington Drive, Bloomingdale, IL, 60108, US

(21) Appl. No.: 12/074,396

(22) Filed: Mar. 4, 2008

Related U.S. Application Data
(60) Provisional application No. 60/905,471, filed on Mar. 7, 2007.

(51) Int. Cl. G01R 33/07

(52) U.S. Cl. 324/207.2; 324/207.25

(57) ABSTRACT

A rotary position sensor for sensing the position of a movable object. The sensor includes a housing that defines a pair of cavities separated by a wall. A magnet, which is adapted to generate a magnetic field, is positioned within one of the cavities. The magnet is adapted to be coupled to the movable object. A magnetic sensor, which is adapted to generate an electrical signal that is indicative of the position of the movable object, is positioned within the other cavity.

### CROSS-REFERENCE TO RELATED AND CO-PENDING APPLICATIONS

This application claims priority to U.S. Provisional Patent Application, Ser. No. 60/905,471, filed on Mar. 7, 2007, entitled, “Rotary Position Sensor”, the contents of which are explicitly incorporated by reference in their entirety.

### BACKGROUND OF THE INVENTION

1. Technical Field

This invention relates, in general, to position sensors. More particularly, this invention relates to a sensor that uses a Hall Effect device to generate a signal indicating positional information.

2. Background Art

Position sensing is used to electronically monitor the position or movement of a mechanical component. The position sensor produces an electrical signal that varies as the position of the component in question varies. Electrical position sensors are included in many products. For example, position sensors allow the status of various automotive components to be monitored and controlled electronically.

A position sensor needs to be accurate, in that it must give an appropriate electrical signal based upon the position measured. If inaccurate, a position sensor could potentially hinder the proper evaluation and control of the position of the component being monitored.

It is also typically required that a position sensor be adequately precise in its measurement. However, the precision needed in measuring a position will obviously vary depending upon the particular circumstances of use. For some purposes, only a rough indication of position is necessary; for instance, an indication of whether a valve is mostly open or mostly closed. In other applications, more precise indication of position may be needed.

A position sensor should also be sufficiently durable for the environment in which it is placed. For example, a position sensor used on an automotive valve may experience almost constant movement while the automobile is in operation. Such a position sensor should be constructed of mechanical and electrical components sufficient to allow the sensor to remain accurate and precise during its projected lifetime, despite considerable mechanical vibrations and thermal extremes and gradients.

In the past, position sensors were typically of the “contact” variety. A contacting position sensor requires physical contact to produce the electrical signal. Contacting position sensors typically consist of potentiometers which produce electrical signals that vary as a function of the component's position. Contacting position sensors are generally accurate and precise. Unfortunately, the wear due to contact during movement of contacting position sensors has limited their durability. Also, the friction resulting from the contact can degrade the operation of the component. Further, water intrusion into a potentiometric sensor can disable the sensor.

One important advancement in sensor technology has been the development of non-contacting position sensors. A non-contacting position sensor (“NPS”) does not require physical contact between the signal generator and the sensing element. Instead, an NPS utilizes magnets to generate magnetic fields that vary as a function of position, and devices to detect varying magnetic fields to measure the position of the component to be monitored. Often, a Hall Effect device is used to produce an electrical signal that is dependent upon the magnitude and polarity of the magnetic flux incident upon the device. The Hall Effect device may be physically attached to the component to be monitored and thus moves relative to the stationary magnets as the component moves. Conversely, the Hall Effect device may be stationary with the magnets affixed to the component to be monitored. In either case, the position of the component to be monitored can be determined by the electrical signal produced by the Hall Effect device.

The use of an NPS presents several distinct advantages over the use of a contacting position sensor. Because an NPS does not require physical contact between the signal generator and the sensing element, there is less physical wear during operation, resulting in greater durability of the sensor. The use of an NPS is also advantageous because the lack of any physical contact between the items being monitored and the sensor itself results in reduced drag.

While the use of an NPS presents several advantages, there are also several disadvantages that must be overcome in order for an NPS to be a satisfactory position sensor for many applications. Magnetic irregularities or imperfections can compromise the precision and accuracy of an NPS. The accuracy and precision of an NPS can also be affected by the numerous mechanical vibrations and perturbations likely be to experienced by the sensor. Because there is no physical contact between the item to be monitored and the sensor, it is possible for them to be knocked out of alignment by such vibrations and perturbations. A misalignment can result in the measured magnetic field at any particular location not being what it would be in the original alignment. Because the measured magnetic field can be different than the measured magnetic field when properly aligned, the perceived position can be inaccurate. Linearity of magnetic field strength and the resulting signal is also a concern.

Devices of the prior art also require special electronics to account for changes in the magnetic field with temperature. The field generated by a magnet changes with temperature and the sensor must be able to differentiate between changes in temperature and changes in position.

The use of electronics in an automotive environment is challenging because of the harsh environmental conditions that the electronics are exposed to in terms of vibration and temperature cycles. Designers of sensors for automotive applications are challenged to provide sensors that will perform in a robust manner over the life of the vehicle while at the same time not incurring excessive costs.

### SUMMARY OF THE INVENTION

It is a feature of the present invention to provide a rotary position sensor.

It is another feature of the present invention to provide a sensor that generates an electrical signal for indicating the position of a movable object. The sensor includes a housing defining first and second cavities. A wall separates the first and second cavities. At least one magnet is positioned within the first cavity. The magnet generates a magnetic field. The magnet is adapted to be coupled with the movable object. At least one magnetic sensor is positioned within the second cavity. The magnetic sensor generates an electrical signal that is indicative of a position of the movable object.

It is an additional feature of the present invention to provide a sensor for sensing movement of a movable object. The sensor includes a housing defining first and second sections. A wall separates the first and second sections. A magnet is positioned within the first section and in proximity to the wall. The magnet generates a magnetic field that is adapted to pass through the wall. A magnetic sensor is positioned within the second section and in proximity to the wall. The magnetic sensor is adapted to sense the magnetic field that has passed through the wall.

It is yet another feature of the present invention to provide a sensor. The sensor includes a housing having first and second cavities. A wall separates the first and second cavities. A rotatable rotor is coupled to the housing in the first cavity. A magnet is coupled with the rotor. The magnet generates a magnetic field. A circuit board is mounted in the second cavity. A magnetic field sensor is coupled to the circuit board. The magnetic field sensor generates an electrical signal that is indicative of a position of the rotor.

### BRIEF DESCRIPTION OF THE DRAWINGS

In the accompanying drawings that form part of the specification, and in which like numerals are employed to designate like parts throughout the same:

FIG. 1 is a top overall perspective view of a rotary position sensor in accordance with the present invention with the shaft shown in exploded form;

FIG. 2 is a bottom overall perspective view of the rotary position sensor of FIG. 1;

FIG. 3 is an exploded perspective view of the rotary position sensor of FIG. 1;

FIG. 4 is a vertical cross-sectional view taken along section line A-A in FIG. 5;

FIG. 5 is a top plan view of the rotary position sensor of FIG. 1 with the cover removed;

FIG. 6 is a bottom plan view of the rotary position sensor of FIG. 1;

FIG. 7 is a perspective view of one embodiment of the magnet of the rotary position sensor of FIG. 1;

FIG. 8 is a perspective view of an alternative magnet design embodiment of the rotary position sensor of FIG. 1; and

FIG. 9 is a perspective view of yet another alternative magnet design embodiment of the rotary position sensor of FIG. 1.

It is noted that the drawings of the invention are not to scale.

### DETAILED DESCRIPTION

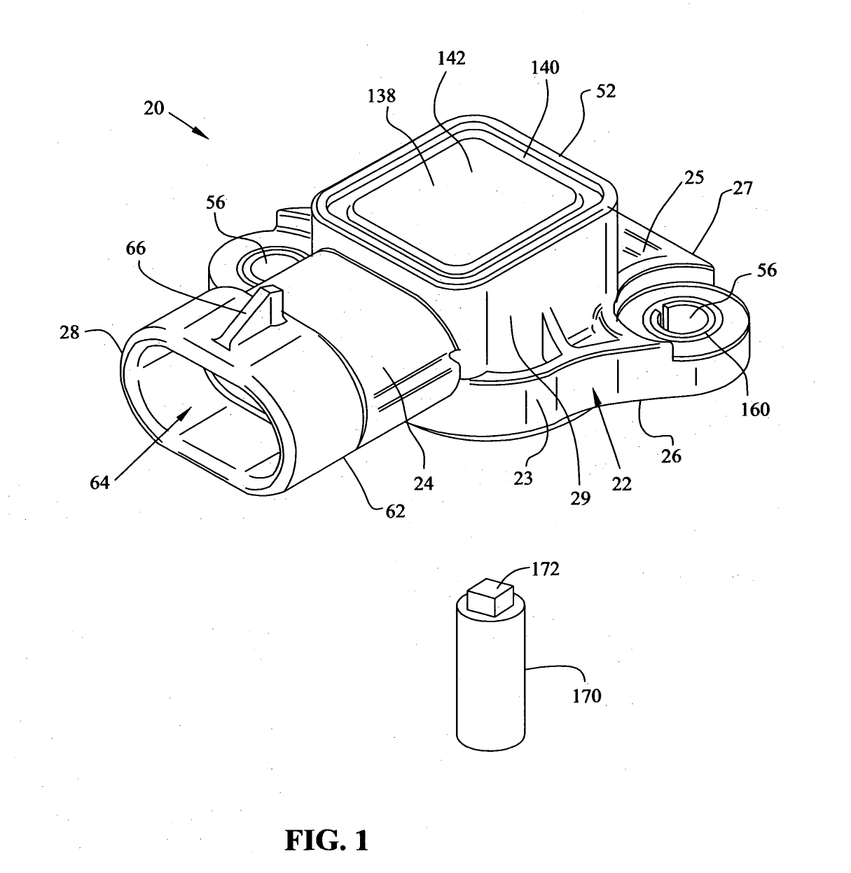

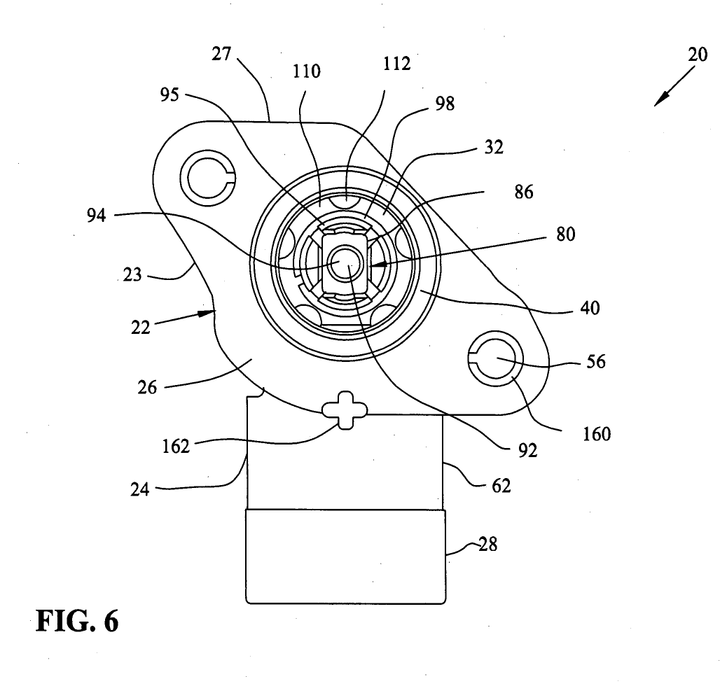

A rotary position sensor assembly 20 according to the present invention is shown in FIGS. 1-6. Rotary position sensor 20 includes, among other elements, a sensor housing 22, a rotor 80, a magnet 100, and a circuit board assembly 120.

### Housing

Sensor housing 22 has a generally oval-shaped base portion 23 and a generally square upper portion 29 unitary with base portion 23. Base portion 23 has a top side 25 and a bottom side 26. A connector portion 24 extends unitarily outwardly from upper portion 29. Housing 22 further defines ends 27 and 28. Housing 22 can be formed from injected molded plastic.

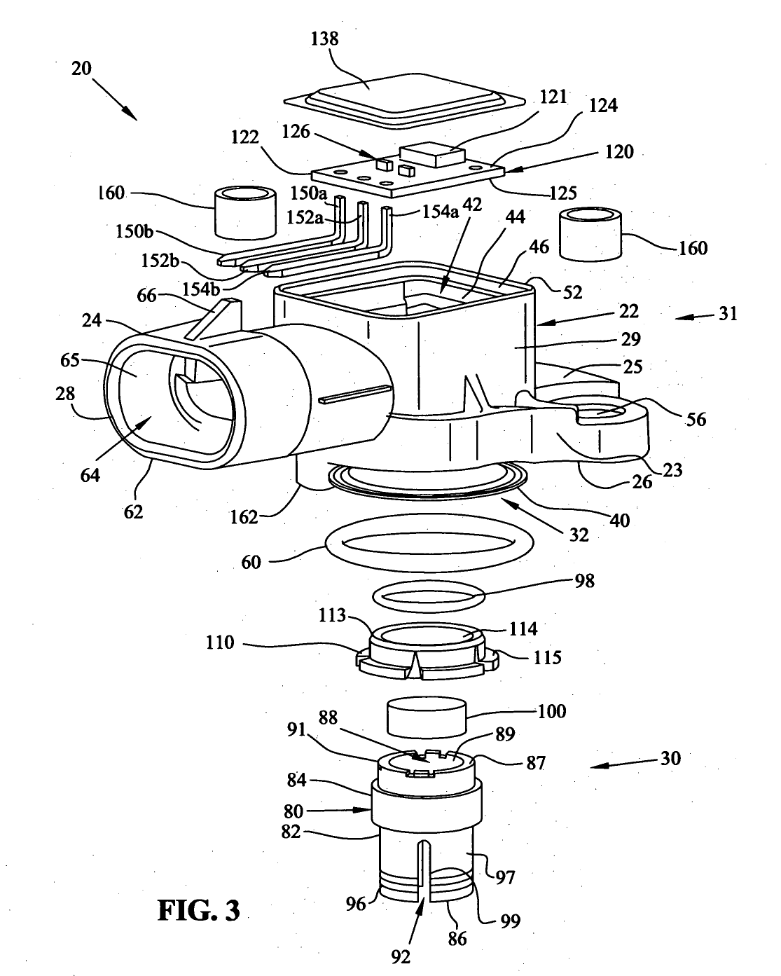

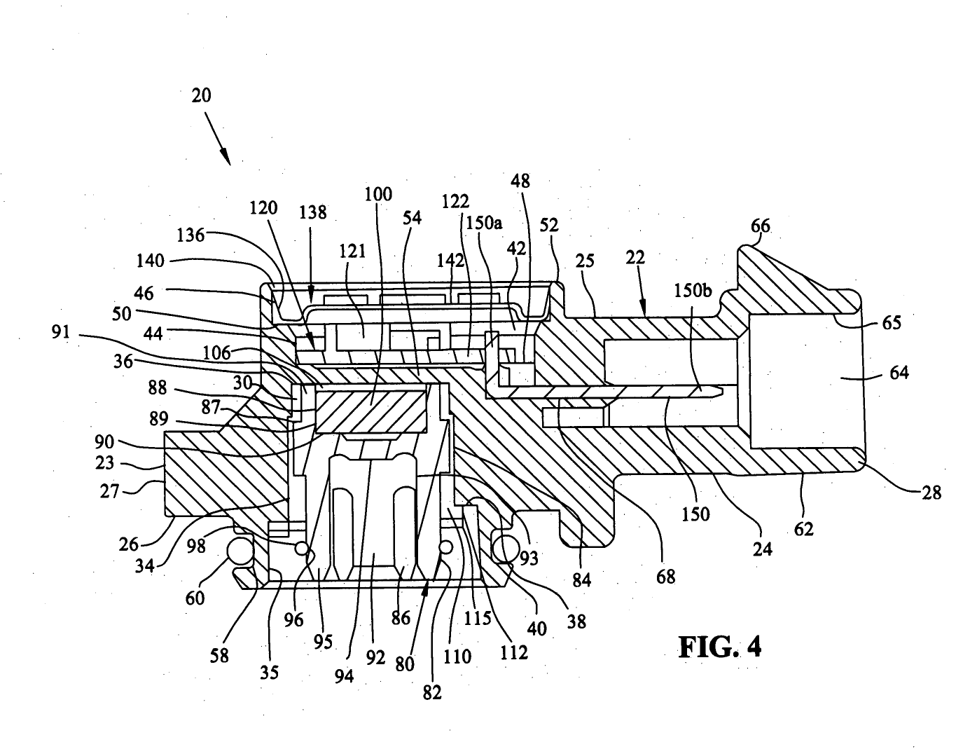

Housing 22 further defines two sections, cavities or enclosures. Specifically, housing 22 had a magnet or rotor section 30 (FIG. 4) that contains a movable rotor 80 and a sensor or electronics section 31 (FIG. 3) that contains a stationary electronic circuit. Rotor section 30 includes a rotor cavity 32 (FIG. 3) that is located and defined in bottom side 26 of housing base portion 23. Sensor section 31 includes a printed circuit board cavity 42 (FIG. 3) that is located in the top side 25 of housing base portion 23.

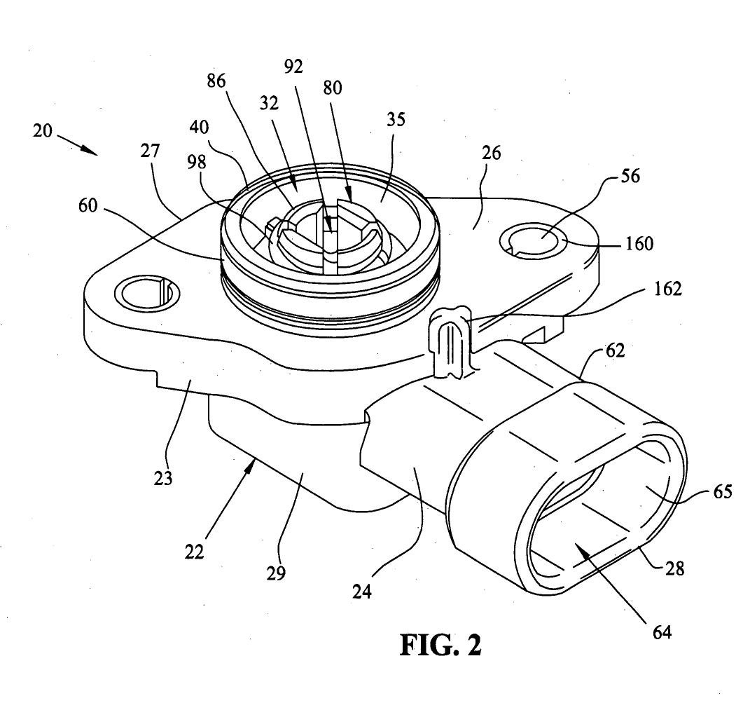

Rotor cavity 32 is defined by circumferentially extending interior vertical side walls 34 and 35 and a bottom horizontal wall 36. Side walls 34 and 35 are contiguous and are generally disposed in an orientation perpendicular to bottom wall 36. Rotor cavity 32 can be generally cylindrical in shape. An annular generally horizontal ledge 38 (FIG. 4) is defined in cavity 32 between side walls 34 and 35. An outer rim 40 of wall 35 defines the exterior circumferential edge of cavity 32. Rim 40 is circular in shape. Housing 22 also defines an alignment tab or feature 162 (FIG. 2) that extends generally normally to, and outwardly from, bottom side 26.

Printed circuit board cavity 42 (FIG. 3) is defined by circumferentially extending vertical side walls 44 and 46 and bottom surface 48 (FIG. 4). Side walls 44 and 46 are contiguous and are disposed in a relationship generally perpendicular to bottom wall 48. Printed circuit board cavity 42 is generally square in shape.

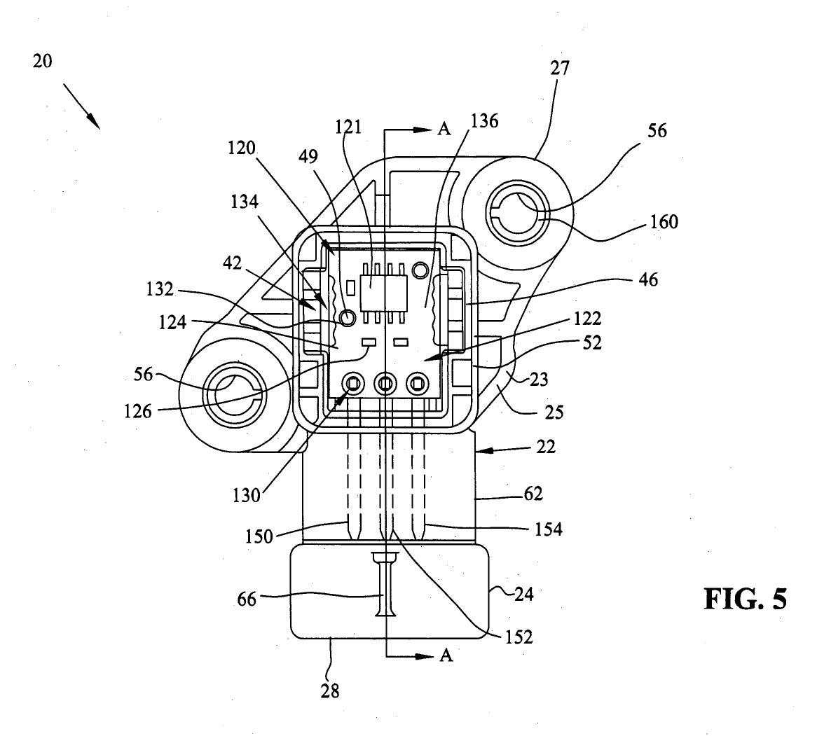

Alignment posts 49 (FIG. 5) extend generally perpendicularly upwardly from the bottom surface 48 of cavity 42. An annular horizontal ledge 50 is located at the base of wall 46 between side walls 44 and 46. A circumferential outer rim 52 (FIG. 4) is defined at the top of wall 46. A generally horizontal separation wall 54 (FIG. 4) separates printed circuit board cavity 42 from rotor cavity 32. Separation wall 54 is unitary with, and oriented substantially perpendicularly to, walls 32 and 44. Bottom surface 36 is located on one side of separation wall 54 and bottom surface 48 is located on the other side of separation wall 54.

A pair of apertures 56 (FIGS. 1-3 and 5) are defined in and pass through base portion 23. Apertures 56 are located in opposing diagonal corners of base portion 23. Metal inserts 160 (FIG. 5) are mounted in apertures 56 by press fitting or the like. A fastener (not shown) is adapted to pass through apertures 56 and inserts 160 to attach housing 22 to an external or other generally stationary object.

A round or annular circumferential slot 58 (FIG. 4) is defined in and located on the outer side of wall 35 below rim 40. A round rubber O-Ring 60 is mounted in slot 58 and is adapted to form a seal with another mounting surface (not shown) to which sensor housing 22 is adapted to be mounted.

Connector portion 24 (FIGS. 1-3 and 5) extends outwardly generally perpendicularly from one side of upper portion 29. Connector portion 24 includes a connector 62 that defines an interior cavity 64, a retaining tab 66, and a passage 68 (FIG. 4). Cavity 64 is defined by an oval-shaped interior circumferential wall 65 that surrounds cavity 64. Retaining tab 66 extends generally normally outwardly from the exterior face of one side of wall 65. A wire harness (not shown) is adapted for attachment to connector 62 and is retained by retaining tab 66 for electrically connecting sensor assembly 20 to another electrical circuit.

### Rotor

A cylindrically-shaped rotor 80 is shown in FIGS. 2-4 mounted in rotor cavity 32. Rotor 80 has an outer surface 82 and defines ends 86 and 87 (FIG. 3). Rotor 80 further defines a circumferential band or ring 84 having a diameter greater than the diameter of rotor 80. Band 84 is located adjacent rotor top end 87. Rotor 80 is formed from injected molded plastic.

Rotor 80 further defines an interior magnet bore 88 located in end 87. Magnet bore 88 is cylindrical in shape and is defined by an annular interior side wall 89, a bottom wall 90 (FIG. 4) that is perpendicular to side wall 89, and an outer rim 91 (FIG. 3) at the outer edge of side wall 89. Magnet bore 88 is adapted to receive magnet 100 (FIG. 3).

Rotor 80 further defines a shaft bore 92 located in lower end 86. Shaft bore 92 is rectangular or square in shape and is defined by an annular side wall 93 (FIG. 4), a bottom wall 94 (FIG. 3) that is perpendicular to side wall 93, and a circumferential rim 95 (FIG. 4) at the outer edge of side wall 93.

Side wall 93 is split into four sections or segments 97 by elongate, generally vertical slots 99 that are defined in and located in side wall 93 and extend between rim 95 and bottom wall 94. Segments 97 extend circumferentially around side wall 93 in spaced-apart and parallel relationship.

Shaft bore 92 and magnet bore 88 are opposed and located at opposite ends of rotor 80. Shaft bore 92 and magnet bore 88 are separated by bottom walls 90 and 94.

A circumferential recess 96 (FIGS. 3 and 4) is defined in and located adjacent rim 95. A metal spring ring 98 is adapted to be seated in recess 96 and adapted to retain rotor 80 on a shaft 170 (FIG. 1).

Rectangular shaft bore 92 is adapted to receive shaft 170 (i.e., the shaft of the particular object whose position is desired to be measured). In the embodiment shown, shaft 170 has a mating feature such as, for example, rectangular end 172. Shaft 170 can be attached to any type of object. For example, shaft 170 may be attached to a bypass or waste gate valve of a turbo-charger that is attached to an engine.

In accordance with the present invention, shaft 170 is secured to rotor 80 as a result of the ring 98 compressing segments 97 against the outer surface of shaft 170.

### Magnet

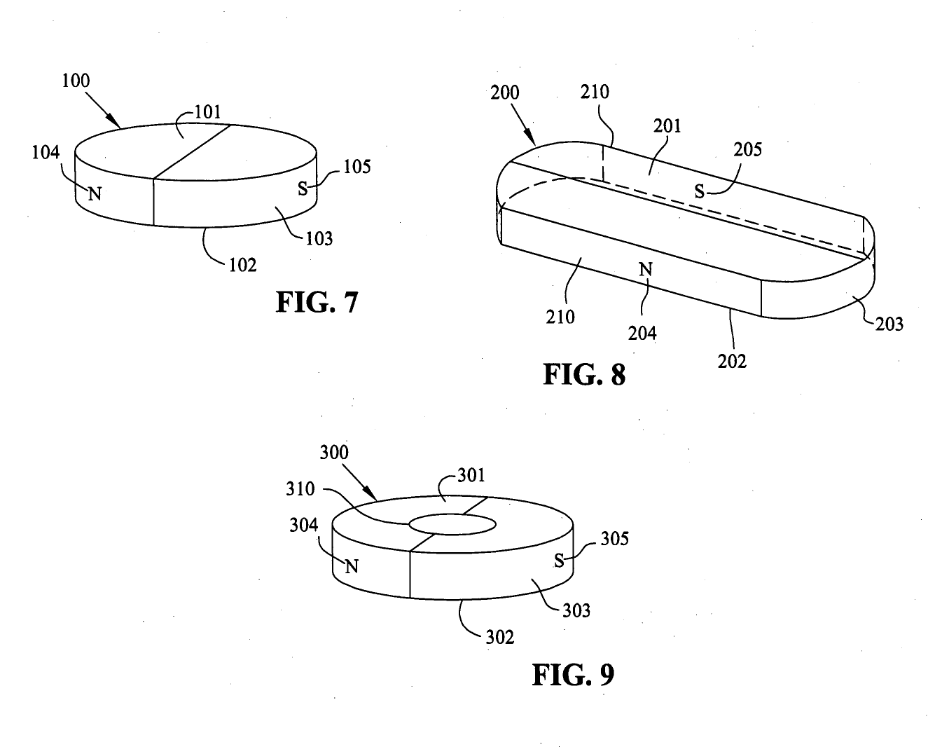

As shown in FIGS. 4 and 7, a cylindrical or disc shaped magnet 100 is adapted to be mounted in magnet bore 88. Magnet 100 is placed in magnet bore 88 and held in place with a heat stake 106 or, alternatively, magnet 100 may be press fit into magnet bore 88.

In the embodiment shown, magnet 100 is a permanent magnet that is polarized such that it has a north pole 104 and a south pole 105 (FIG. 7). Magnet 100 can be made from several different magnetic materials such as, but not limited to, ferrite or samarium cobalt or neodymium-iron-boron. In one embodiment, magnet 100 can be a neodymium-iron boron magnet that is round in shape. Other types and shapes of magnets may also be used. Magnet 100 defines a top surface 101, a bottom surface 102, and a peripheral side surface 103. Top surface 101 and bottom surface 102 are parallel and opposed to each other.

After rotor 80 is placed into cavity 32, rotor 80 is retained or held in rotor cavity 32 by a circular retaining ring 110 (FIGS. 3 and 4). Retaining Ring 110 is defined by a circumferential wall 113 that defines a central aperture 114 and a lower circumferential flange 115 that extends radially outwardly from the outer surface of wall 114.

Retaining ring 110 is positioned in cavity 32 in a relationship surrounding rotor 80 and, more particularly, in a relationship abutting the lower flange of rotor ring 80. Heat stakes 112 (FIG. 4) are formed between flange 115 and wall 38 by the localized heating and melting of a portion of flange 115 and wall 38. Heat stakes 112 fasten retaining ring 110 to housing 22. Rotor 80 is supported by retaining ring 110 for rotary movement within cavity 32.

### Circuit Board

FIGS. 3-5 depict a circuit board assembly 120 mounted in printed circuit board cavity 42. Circuit board assembly 120 includes a printed circuit board 122 having a top surface 124, a bottom surface 125, and plated through-holes 130 extending between the top surface 124 and bottom surface 125. Printed circuit board 122 can be a conventional printed circuit board formed from FR4 material.

A sensor 121 such as, for example, a magnetic field sensor is mounted to top surface 124 by conventional electronic assembly techniques such as, for example, soldering. Magnetic field sensor 121 can be a model number MLX90316 integrated circuit from Melexis Corporation of leper, Belgium. The MLX90316 integrated circuit is adapted to measure the magnetic field in two directions or vectors parallel to the integrated circuit surface. The MLX90316 integrated circuit is also adapted to include internal Hall Effect devices. Other electronic components 126 (FIG. 3) such as capacitors, resistors, inductors, and other types of conditioning, amplifying and filtering devices are mounted to the top surface 124. Magnetic field sensor 121 and electronic components 126 are adapted to be mounted to top surface 124 using conventional electronic assembly techniques.

Printed circuit board 122 further defines a plurality of postholes 132 (FIG. 5) through which elongate cylindrically-shaped alignment posts 49 (FIG. 5) extend. Alignment posts 49 extend upwardly and perpendicularly to bottom wall 48. Postholes 132 retain and align printed circuit board 122 to housing 22. After postholes 132 are placed over posts 49, posts 49 can be partially melted using heat to form a heat stake. Another pair of heat stakes 134 (FIG. 5) are formed on opposing walls 44 extending over top surface 124 to further retain printed circuit board 122 in cavity 42. A potting compound 136 (FIG. 4) such as, for example, a silicone gel is placed over printed circuit board 122 to seal printed circuit board 122 from the outside environment.

A generally square-shaped metal cover 138 (FIGS. 1, 3 and 4) is placed over cavity 42 and printed circuit board 122. Cover 138 has a generally U-shaped outer peripheral spring section, rim or wall 140 that is biased against side walls 46 after assembly. Spring section 140 retains cover 138 to housing 20. Cover 138 has a center portion 142 (FIG. 4). Alternatively, cover 138 can be formed from plastic and heat staked to side walls 46.

Several generally L-shaped electrically conductive metal terminals 150, 152 and 154 (FIG.3) are mounted within housing 22. Terminals 150, 152 and 154 extend generally horizontally from printed circuit board cavity 42 outwardly through passage 68 (FIG. 4) and into connector cavity 64.

Terminal 150 defines ends 150a and 150b; terminal 152 defines ends 152a and 152b; and terminal 154 defines ends 154a and 154b. Ends 150a, 152a, and 154a are bent at a generally ninety (90) degree angle relative to the remainder of the terminals 150, 152, and 154 respectively. Terminal ends 150a, 152a and 154a are soldered to printed circuit board 122 and are adapted to extend into cavity 64 where they are adapted to be connected to another electrical connector and wire harness (not shown).

### Operation

In accordance with the present invention, rotary position sensor assembly 20 is used to ascertain the position of a rotating or movable object such as shaft 170 which is adapted for connection to a wide variety of rotating or moving objects including, for example, a turbo-charger bypass or waste gate valve, a throttle valve, an exhaust gas re-circulation valve, or any other type of valve.

When shaft 170 is rotated, rotor 80 and magnet 100 are also rotated with respect to sensor 121 mounted to printed circuit board 122 that is fixed within cavity 42. Sensor 121 is spaced from magnet 100. Wall 54 and printed circuit board 122 separate sensor 121 and magnet 100. The magnetic field produced by magnet 100 passes through wall 54 and printed circuit board 122 where it is sensed by sensor 121. The magnetic field can vary in magnitude of field strength and in polarity depending upon the location at which the magnet parameters (lines of flux) are measured. As magnet 100 is rotated, the magnetic field has a vector that changes direction and can be sensed about two axes that are parallel to the top surface of sensor 121.

Sensor 121 produces an electrical output signal that changes in response to the position of magnet 100 and the position of shaft 170. As the magnetic field generated by the magnet 100 varies with rotation of the shaft, the electrical output signal produced by sensor 121 changes accordingly, thus allowing the position of shaft 170 to be determined or ascertained. Sensor 121 senses the changing magnetic field as magnet 100 is rotated. The electrical signal produced by sensor 121 is indicative of the position of shaft 170. In one embodiment, the electrical signal produced by sensor 121 can be proportional to the position of shaft 170.

The present invention has several advantages. The mounting of the movable mechanical components (rotor and magnet) in a separate housing section, or cavity, apart from the electronic components (hall effect sensor) allows the electronic components to be better isolated, protected, and sealed from outside environmental conditions. This allows the sensor to be used in more demanding applications with high heat and humidity.

Also, the use of two separate housing sections or cavities placed back to back and separated by a single wall allows for a compact sensor design.

Further, the use of the MLX90316 integrated circuit hall effect sensor reduces or eliminates the need for temperature compensation electronics due the fact that the MLX90316 device measures the direction of the magnetic filed vectors in orthogonal axes and uses this information to compute position.

### Alternative Magnet Embodiments

FIG. 8 illustrates an alternative magnet embodiment 200 which is similar to magnet 100 except that magnet 200 is generally oval in shape and includes a pair of flat sections or areas 210. Magnet 200 includes a top horizontal surface 201, a bottom horizontal surface 202, and another circumferentially extending side vertical surface 203. Magnet 200 further defines a north pole 204 and a south pole 205. Opposed parallel flat sections 210 are located on opposite sides of side surface 203 in a relationship generally normal to top and bottom surfaces 201 and 202 respectively.

Flat surfaces 210 cause the magnetic field detected by sensor 121 to have a more linear output signal as magnet 200 is rotated which allows for a more precise determination of the position of any objects that are coupled with magnet 200. The use of a magnet with flat side sections also allows for an output signal with improved linearity.

FIG. 9 illustrates yet another magnet embodiment similar to magnet 100 except that an aperture 310 is additionally defined in, and extends through, the center of the magnet. Aperture 310 is adapted to receive a shaft (not shown). Magnet 300 is disc or cylindrical in shape and includes a top horizontal surface 301, a bottom horizontal surface 302, and an outer circumferential vertical side surface 303. Magnet 300 defines a north pole 304 and a south pole 305.

### Conclusion

While the invention has been taught with specific reference to these embodiments, someone skilled in the art will recognize that changes can be made in form and detail without departing from the spirit and the scope of the invention. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. A sensor for sensing a movable object, comprising:
a housing defining first and second cavities;
a wall separating the first and second cavities;
at least one magnet positioned in the first cavity, the magnet generating a magnetic field and adapted to be coupled with the movable object; and
at least one magnetic sensor positioned within the second cavity, the magnetic sensor generating an electrical signal that is indicative of a position of the movable object.

2. The sensor of claim 1, wherein the magnetic sensor is mounted to a printed circuit board.

3. The sensor of claim 1, wherein the magnetic sensor is a hall effect device.

4. The sensor of claim 1, wherein the magnetic sensor is adapted to detect the direction of the magnetic field.

5. The sensor of claim 1, wherein the magnet is mounted to a rotor.

6. The sensor of claim 5, wherein the magnet is heat staked to the rotor.

7. The sensor of claim 5, wherein a retaining ring retains the rotor in the first cavity.

8. The sensor of claim 1, wherein a cover is mounted over the second cavity.

9. The sensor of claim 1, wherein the movable object is a valve.

10. The sensor of claim 1, wherein the movable object is a turbocharger bypass valve.

11. A sensor for sensing the movement of a movable object, comprising:
a housing defining a first section and a second section;
a wall separating the first and second sections;
at least one magnet positioned within the first section and in proximity to the wall, the magnet generating a magnetic field that is adapted to pass through the wall; and
at least one magnetic sensor positioned within the second section and in proximity to the wall, the magnetic sensor being adapted to sense the magnetic field that has passed through the wall.

12. The sensor according to claim 11, wherein the wall has first and second surfaces, the magnet being positioned adjacent to the first surface and the magnetic sensor being positioned adjacent to the second surface.

13. The sensor according to claim 11, wherein the magnet has at least one flat section.

14. The sensor according to claim 11, wherein the magnet defines at least one central through-hole.

15. A sensor comprising:
a housing defining first and second cavities;
a wall separating the first and second cavities;
a rotatable rotor in the first cavity and coupled to the housing;
a magnet coupled to the rotor and adapted to generate a magnetic field;
a circuit board mounted in the second cavity; and
a magnetic field sensor coupled to the circuit board and adapted to generate an electrical signal that is indicative of a position of the rotor.

16. The sensor according to claim 15, wherein the rotor defines respective bores for the magnet and a shaft.

17. The sensor according to claim 16, wherein the magnet is mounted in the magnet bore.

18. The sensor according to claim 15, wherein a cover seals the second cavity.

19. The sensor of claim 15, wherein a plurality of terminals extend between the second cavity and a third cavity.

20. The sensor of claim 15, wherein a retaining ring retains the rotor in the first cavity.
